(19) United States
(12) Patent Application Publication
(10) Pub. No.: US 2025/0318236 A1
(43) Pub. Date: Oct. 9, 2025

(54) Field Plate

(71) Applicant: X-FAB Global Services GmbH, Erfurt (DE)

(72) Inventor: Alexander Hölke, Erfurt (DE)

(21) Appl. No.: 19/086,701

(22) Filed: Mar. 21, 2025

(30) Foreign Application Priority Data
Mar. 21, 2024 (GB) 2404035.4

(51) Int. Cl. H10D 64/00; H10D 30/65; H10D 84/83

(52) U.S. Cl. CPC H10D 64/112; H10D 30/65; H10D 84/835

(57) ABSTRACT

An integrated circuit including a high voltage semiconductor device having a first doped region, a second doped region, and a drift region located between the first doped region and the second doped region. The circuit includes a plurality of stacked metal layers, a metal structure overlapping the drift region, and a field plate structure arranged between the metal structure and the drift region. The field plate structure includes an array of floating field plates, and a pair of field plates, having first and second field plates, wherein the pair of field plates overlaps the array of floating field plates. The first field plate and the second field plate are separated by a gap, and the gap is arranged diagonally over the drift region.

### IMPROVED FIELD PLATE

This application claims priority to UK Patent Application No. GB 2404035.4 filed on Mar. 21, 2024 and entitled Improved Field Plate, the entire contents of which are hereby incorporated by reference.

### TECHNICAL FIELD

The current disclosure relates to improved field plates, and in particular to improved field plates in integrated circuits with a high voltage semiconductor device.

### BACKGROUND

Lateral high voltage (HV) semiconductor devices in integrated circuits are used for AC/DC converters and power switches. For example, lateral double diffused MOS (LDMOS) transistors are used for high voltage (HV) applications in integrated circuits. The reliability and breakdown characteristics of the LDMOS depend on the drift region (the lightly doped region between the drain and source). Metal lines over the drift region can significantly alter the electric field distribution therein and thereby lower the breakdown voltage or otherwise have a negative impact on the device performance. This restricts the design freedom for the integrated circuit and may require off-chip connections (e.g. wire bonding).

Koicho Endo (Toshiba), “Power Semiconductor Integrated Circuit Device Without Concentration of Electric Field,” U.S. Pat. No. 5,315,139 proposes a resistor placed between the HV drift region and the wiring layer passing over it. However, the resistor introduces an undesired leakage current to the HV device when using existing layers of the given CMOS process such as the poly-Si-layer.

Akio Nakagawa et.al. (Toshiba), “Planar Semiconductor Device having High Breakdown Voltage,” U.S. Pat. No. 5,086,332 describes how a lower leakage can be achieved with a special semi-insulating polysilicon (SIPOS). However, SIPOS requires additional fabrication steps and the leakage is still significant, especially at higher temperatures.

Tomohide Terashima (Mitsubishi), “Structure for Preventing Electric Field Concentration in Semiconductor Device,” EP Publication No. 0461877A2 describes field plate strips arranged so that a uniform electric field is achieved by capacitive coupling between them. A small metal line can then be passed over the field plates, if the capacitive coupling between this metal line and the field plates is negligible compared to the coupling between the field plates.

### SUMMARY

Aspects of the disclosure provide integrated circuits as set out in the accompanying claims.

Alternatively, aspects of the disclosure may be defined by any of the following numbered paragraphs.

1. An integrated circuit comprising:
a high voltage semiconductor device comprising a first doped region, a second doped region, and a drift region located between the first doped region and the second doped region;
a plurality of stacked metal layers;
a metal structure overlapping the drift region;
a field plate structure arranged between the metal structure and the drift region, wherein the field plate structure comprises:
an array of floating field plates; and
a pair of biased field plates, wherein the pair of biased field plates overlaps the array of floating field plates.

2. An integrated circuit according to paragraph 1, wherein said array of floating field plates are formed in a polysilicon layer or a first metal layer of said plurality of stacked metal layers.

3. An integrated circuit according to paragraph 1 or 2, wherein said pair of biased field plates are formed in a second metal layer of said plurality of stacked metal layers.

4. An integrated circuit according to any preceding paragraph, wherein the floating field plates have an extended dimension arranged substantially perpendicular to a current through the drift region when in use.

5. An integrated circuit according to any preceding paragraph, wherein the floating field plates have a rectangular shape.

6. An integrated circuit according to paragraph 5, wherein the rectangular shape has a short side with a dimension in the range of 1 μm to 5 μm, and a long side with a dimension in the range of 1 μm to 10 mm.

7. An integrated circuit according to any one of the preceding paragraphs, wherein the pair of biased field plates comprises a first field plate electrically connected to a low voltage point, and a second field plate electrically connected to a high voltage point.

8. An integrated circuit according to any preceding paragraph, wherein the first field plate is electrically connected to the first doped region, and the second field plate is electrically connected to the second doped region.

9. An integrated circuit according to any preceding paragraph, wherein the first field plate and the second field plate are separated by a gap in the metal layer, and wherein the gap is arranged diagonally over the drift region.

10. An integrated circuit according to paragraph 9, wherein the gap has a width in the range of 0.5 μm to 5 μm.

11. An integrated circuit according to any one of the preceding paragraphs, wherein the pair of biased field plates covers a substantially rectangular area, and wherein each of the first and second field plates has a triangular shape.

12. An integrated circuit according to any one of the preceding paragraphs, wherein the pair of biased field plates are arranged with respect to the array of floating field plates such that an electric potential increases substantially linearly from a first floating field plate located closest to the second doped region to a last floating field plate located closest to the first doped region.

13. An integrated circuit according to any one of the preceding paragraphs, further comprising a one or more further pairs of biased field plates arranged over the drift region and overlapping the array of floating field plates.

14. An integrated circuit according to paragraph 13, wherein the gap between field plates of the pair of biased field plates and a gap between field plates of the one or more further pairs of biased field plates together form a zig-zag pattern over the drift region.

15. An integrated circuit comprising:
a high voltage semiconductor device comprising a first doped region, a second doped region, and a drift region located between the first doped region and the second doped region;
a plurality of stacked metal layers;
a metal structure overlapping the drift region; and
a field plate structure arranged between the metal structure and the drift region, wherein the field plate structure comprises a metal layer defining a slot.

16. An integrated circuit according to paragraph 15, wherein said slot separates the metal layer into two parts and wherein each part provides a continuous metal cover over the drift region.

17. An integrated circuit according to paragraph 15 or 16, wherein said metal layer is formed in one of said plurality of stacked metal layers.

18. An integrated circuit according to paragraph 15, 16 or 17, wherein said metal layer is located in Metal 4 or Metal 5 of said plurality of stacked metal layers.

19. An integrated circuit according to any one of paragraphs 15 to 18, wherein the slot has a width dimension in the range of 1 μm to 5 μm.

20. An integrated circuit according to any one of paragraphs 15 to 19, wherein the slot has a longitudinal axis substantially perpendicular to a direction from said first doped region to said second doped region.

21. An integrated circuit according to any one of paragraphs 15 to 20, wherein the slot is positioned substantially half way between said first doped region and said second doped region.

22. An integrated circuit according to any one of paragraphs 15 to 21, wherein the slot is located under the metal structure.

23. An integrated circuit according to paragraph 22, wherein said slot is the only slot, formed in said metal layer, which is located under the metal structure.

24. An integrated circuit according to any preceding paragraph, wherein said metal structure completely covers said drift region.

25. An integrated circuit according to any preceding paragraph, wherein said metal structure completely covers said field plate structure.

26. An integrated circuit device comprising:
an integrated circuit according to any preceding paragraph;
a high voltage region comprising the high voltage semiconductor device of said integrated circuit; and
a low voltage region comprising a plurality of low voltage semiconductor devices;
and wherein said plurality of stacked metal layers comprises metal lines configured to provide electrical connections to the high voltage semiconductor device and to the plurality of low voltage semiconductor devices.

Specific embodiments are described below with reference to the drawings.

### BRIEF DESCRIPTION OF DRAWINGS

FIG. 1 shows a schematic top view of an integrated circuit;

FIG. 2A shows a schematic cross section of a HV semiconductor device;

FIG. 2B shows the same HV device, with a metal line in the fourth metal layer over the drift region;

FIG. 3 shows a schematic perspective view of a field plate structure;

FIG. 4A shows a schematic top view of a field plate structure and a part of a HV semiconductor device;

FIG. 4B shows another schematic top view of the field plate structure;

FIG. 4C shows a schematic cross section of the HV semiconductor device, comprising the field plate structure;

FIG. 5 shows a schematic top view of a HV device comprising a field plate structure;

FIG. 6 shows a schematic top view of a large-area HV semiconductor device;

FIG. 7 shows a schematic top view of another field plate structure;

FIG. 8 shows a schematic cross section of a HV semiconductor device, comprising a field plate structure;

FIG. 9 shows a schematic cross section of a HV semiconductor device, comprising a field plate structure;

FIG. 10A shows a graph plotting the change in breakdown drain to source voltage; and

FIG. 10B shows a graph plotting the change in breakdown drain to source voltage.

### DETAILED DESCRIPTION

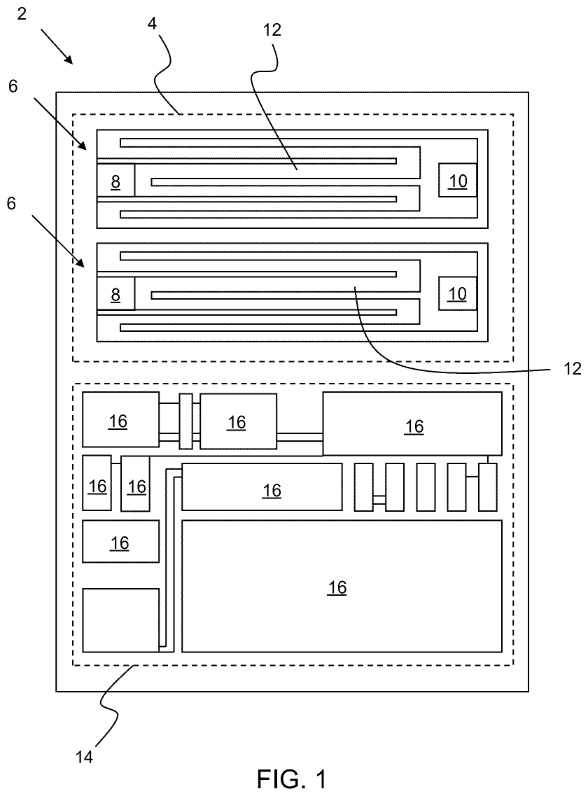

FIG. 1 shows a schematic top view of an integrated circuit 2 (e.g. an AC/DC converter) with a HV region 4 comprising two LDMOS transistors 6, comprising a source 8, and a drain 10 and a drift region 12 therebetween. The integrated circuit 2 further comprises a low voltage (LV) region 14 comprising a plurality of LV devices 16. The HV region 4 and LV region 14 are formed on the same semiconductor wafer. The LV devices 16 are typically CMOS devices formed in conventional CMOS processes. The LV devices typically comprise transistors, diodes, resistors, and capacitors.

To avoid high electric field densities in the drift region 12, there are no metal lines or connections overlapping the drift region 12. Hence, external connections to drain pad 10 have to be provided. For example, this is often realized through wire bonding to metal connections pads. This introduces further manufacturing steps, longer connections and additional points of potential device failure.

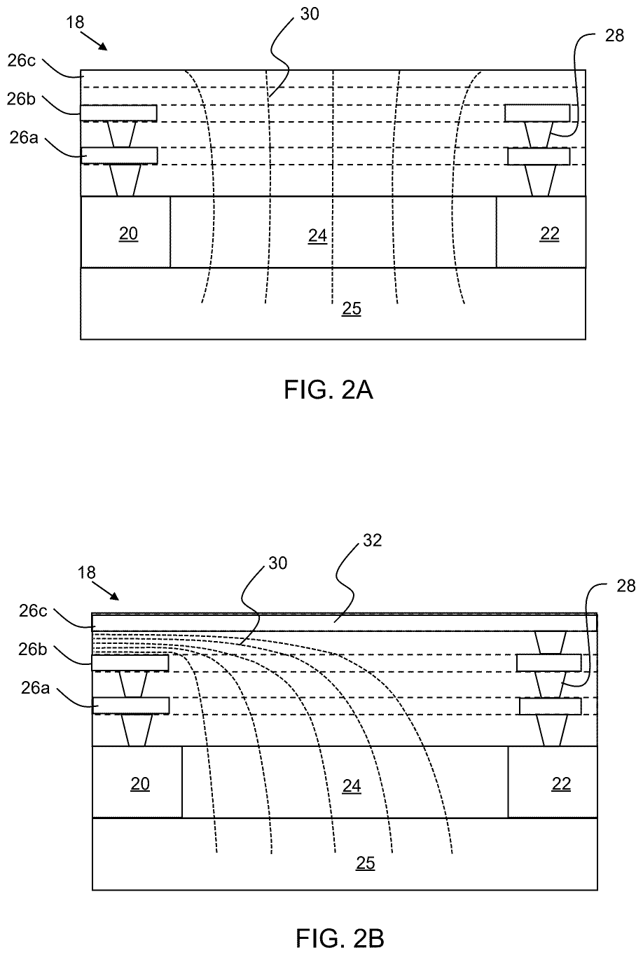

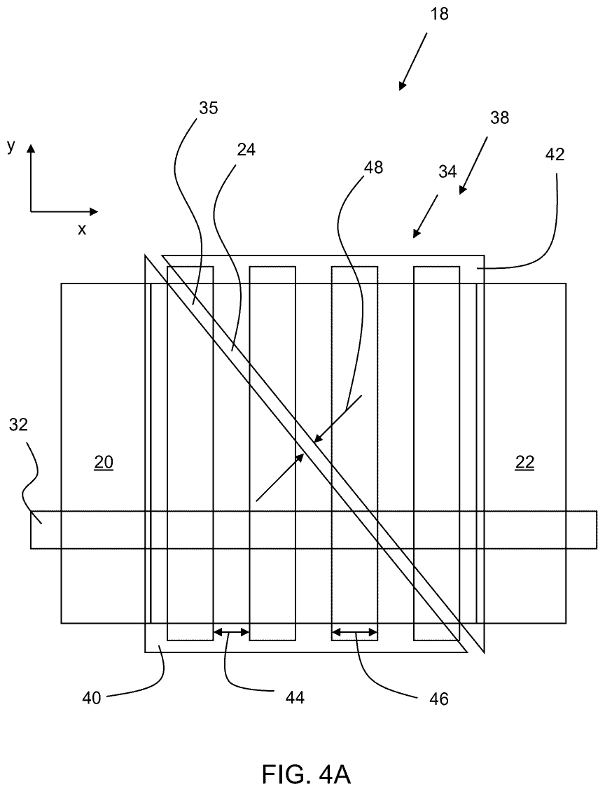

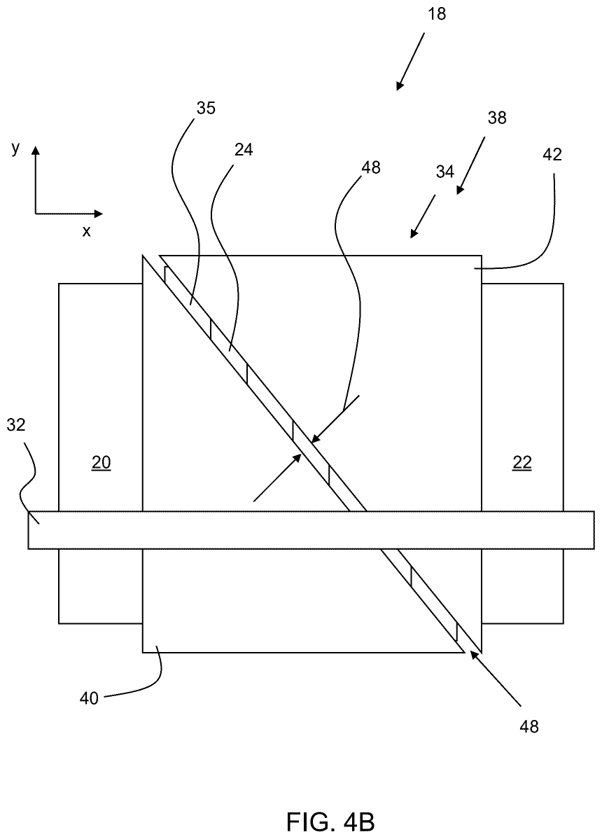

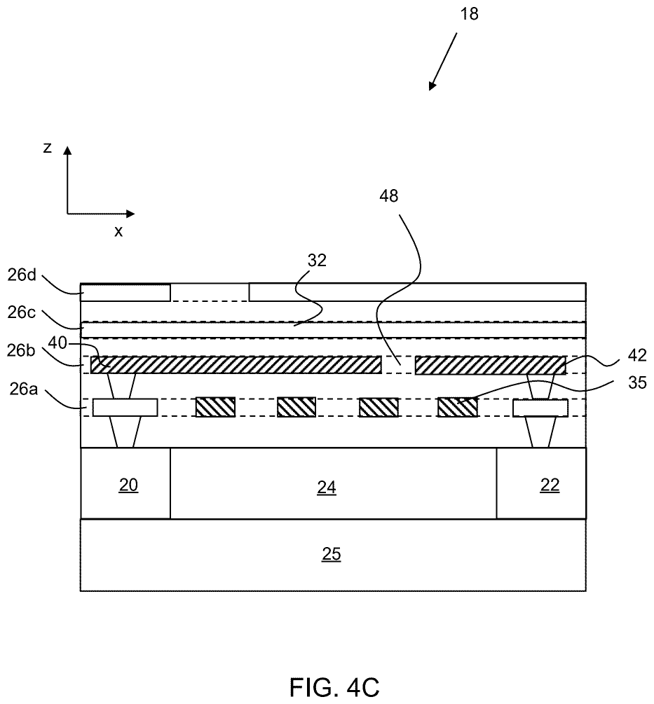

FIG. 2A shows a schematic cross section of a HV semiconductor device 18 (e.g. an LDMOS). The HV semiconductor device 18 may be the LDMOS transistor 6 described in relation to FIG. 1 above. The device 18 comprises a source region 20, a drain region 22 and a drift region 24 between. The device 18 comprises a plurality of metal layers 26a to 26d (only layers 26a to 26c are shown in FIGS. 2A and 2B, whereas layers 26a to 26d are shown in FIG. 4C). The metal layers are Metal 1 (Metal One) 26a (closest to the underlying semiconductor layer), Metal 2 (Metal Two) 26b, Metal 3 (Metal Three) 26c, and Metal 4 (Metal Four) 26d. The metal layers 26a to 26d are typically formed in a CMOS back-end-of-line (BEOL) process to form a backend stack. The metal layers 26a to 26d are separated by interdielectric layers (e.g. comprising silicon oxide) and connected by vias 28 going through the interdielectric layers. The electric field lines 30 (dashed lines) are substantially uniformly distributed in and above the drift region 24. The active silicon layer comprising source region 20 and drain region 22 is located on a substrate 25, which may be a silicon substrate or a silicon on insulator (SOI) substrate for example.

FIG. 2B shows the same HV device 18 but with a metal line 32 in the 3rd metal layer 26c (Metal 3) over the drift region 24. The metal line 32 distorts the electric field lines 30 and creates regions of high electric field density. Local regions of high field density can lower the breakdown voltage. In the shown example, the metal line 32 is connected to the high terminal (corresponding with drain region 22) of the lateral HV device and pushes the electric field towards the low terminal (corresponding with source region 20) creating a region of high field density there.

To at least partly solve this problem, the present disclosure provides a field plate structure located between the drift region and any overlying metal lines. The field plate structure shields the drift region and can provide a more uniform electric field distribution beneath the metal line.

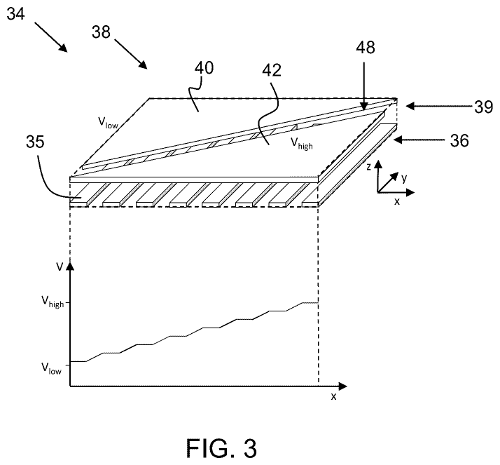

FIG. 3 shows a schematic perspective view of a field plate structure 34 and a plot of the voltage along a length direction (x) relative to the field plate structure 34. The field plate structure comprises an array of floating field plates 35 in a first layer 36 (e.g. Poly or Metal 1) and a pair of biased field plates 38 overlapping the floating field plates 35 in a second layer 39 (e.g. Metal 1, Metal 2 or Metal 3). The pair of biased field plates 38 comprises a first field plate 40 connected to a low voltage point (e.g. to the source) and a second field plate 42 connected to a high voltage point (e.g. to the drain). For example, if the floating field plates 35 are located in the Poly-layer, then the pair of biased field plates can be located in Metal 1, and metal routing can be located in Metal 2 and above. If the floating field plats are located in Metal 1, then the pair of biased field plates 38 can be located in Metal 2 and the metal routing can be located in Metal 3 and above. The Poly layer is the same layer in which the gate poly is located. The floating field plates 35 may therefore be formed in the same process steps of depositing and patterning as the gate poly of the device.

The first and second field plates 40 and 42 have substantially triangular shapes with a gap 48 between them. The triangular shapes have a corner with a right angle and together cover a substantially rectangular area. The gap 48 runs diagonally over the array of floating field plates 35. The angle of the gap 48 relative to the length direction (x-axis) may be in the range of 30° to 60°. The gap 48 may be in the range of 2 μm to 4 μm. Due to tooling/manufacturing constraints, the substantially triangular shape may comprise a substantially flat or a rounded tip.

The array of floating field plates 35 may comprise rectangular strips of metal or polysilicon. The strips are arranged in the length direction (x) with their longitudinal axis in the width direction (y). The extended dimension of the strips may be in the range of 1 μm to 10 mm, and typically covers the whole width of the underlying LDMOS. The gap/spacing between strips may be in the range 0.5 μm to 5 μm.

As can be seen from the plot in the lower part of FIG. 3, the voltage at the floating field plates 35 increases in the x-direction. The first floating field plate 35 (leftmost) is mostly covered by the first field plate 40 (connected to the low voltage point), while the last floating field plate 35 (rightmost) is mostly covered by the second field plate 42 (connected to the high voltage point).

FIG. 4A shows a schematic top view of a field plate structure 34 and a part of a HV semiconductor device 18. The field plate structure 34 is shown as transparent (with only an outline shown) so that the underlying semiconductor regions are visible. The field plate structure 34 may be the field plate structure 34 described in relation to FIG. 3 above. The device 18 comprises a source region 20, a drain region 22, and a drift region 24 therebetween. The field plate structure 34 covers the drift region 24. In particular, an array of floating field plates 35 are arranged along the x-direction over the drift region 24 between the source region 20 and the drain region 22. The floating field plates 35 have a rectangular shape with their extended dimension substantially along the y-direction (the width direction of the drift region 24). The floating field plates 35 have a width 46 (along x) and a spacing 44.

A pair of biased field plates 38 are arranged over the floating field plates 35. The pair 38 comprises a first field plate 40 having the shape of a right angled triangle, and a second field plate 42 having the shape of a corresponding right angled triangle. The first and second field plates are separated by a gap 48. A metal line 32 crosses over the field plate structure 34.

FIG. 4B shows the same schematic top view as FIG. 4A but with opaque features of the field plate structure 34 to illustrate their respective positions. For ease of understanding, FIGS. 4A and 4B show the triangular field plates 40, 42 as covering a larger area than the underlying floating field plates 35. However, in certain embodiments, the pair of biased field plates may have the same width as the array of floating field plates and may cover substantially the same area over the drift region 24.

FIG. 4C shows a schematic cross-section of the HV semiconductor device 18, comprising the field plate structure 34 of FIGS. 3, 4A and 4B. The HV device comprises four stacked metal layers 26a to 26d (Metal 1 to Metal 4) separated by dielectric layers. The first metal layer 26a is directly connected to the source region 20 and the drain region 22. The floating field plates 35 are also located in the first metal layer 26a, and the pair of biased field plates 38 (comprising first field plate 40 and second field plate 42) are located in the second metal layer 26b. The metal line 32 over the drift region 24 is located in the third metal layer 26c. The metal line 32 may completely cover the drift region 24. The field plate structure allows for further metal lines and routing in the fourth metal layer 26d as well, or even higher metal levels depending on the given CMOS process. It is an advantage of this embodiment, and related embodiments, that there can be a complete metal covering at the top of the device. For example, the metal line 32 and/or further metal lines or routing in the fourth metal layer 26d, or higher metal levels, can completely cover the drift region 24 and/or the floating metal plates 35 and/or the pair of biased field plates 38. The HV semiconductor device 18 comprises or is located on a substrate 25. The substrate 25 may be a silicon on insulator (SOI) substrate, or silicon-on-sapphire, or GaN-on-Si for example.

The width of the pair of biased field plates 38 (y direction) can be set to some extent by adjusting the angle of the gap between the plates 40 and 42. However, for HV devices with dimensions on the order of mm, the pair of biased field plates 38 can be a unit cell that is repeated to cover a larger area. The gap between plates of multiple unit cells can then form a zig-zag pattern. The longitudinal dimension of the floating field plates 35 can be extended to cover the width (y direction) of the drift region 24 and the number of floating field plates 35 increased to cover the length (x direction) of the drift region 24.

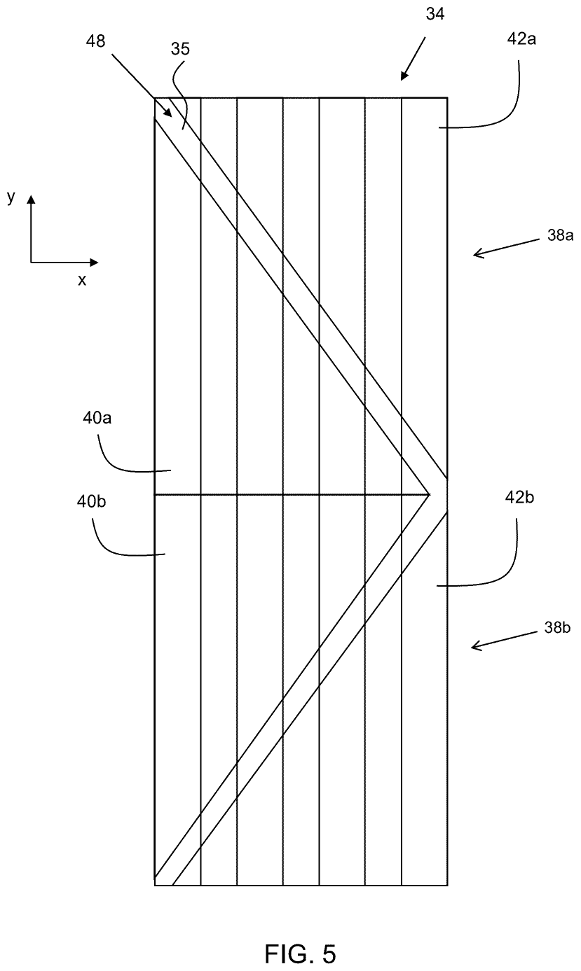

FIG. 5 shows a schematic top view of a field plate structure 34 comprising two pairs of biased field plates 38a and 38b comprising respective plates 40a, 42a and 40b, 42b. The biased field plates 38a, 38b overlap floating field plates 35. Neighboring plates (e.g. 40a and 40b) that are connected to the same voltage may be formed from a single part of a metal layer. That is, there may be no physical line or marker between them.

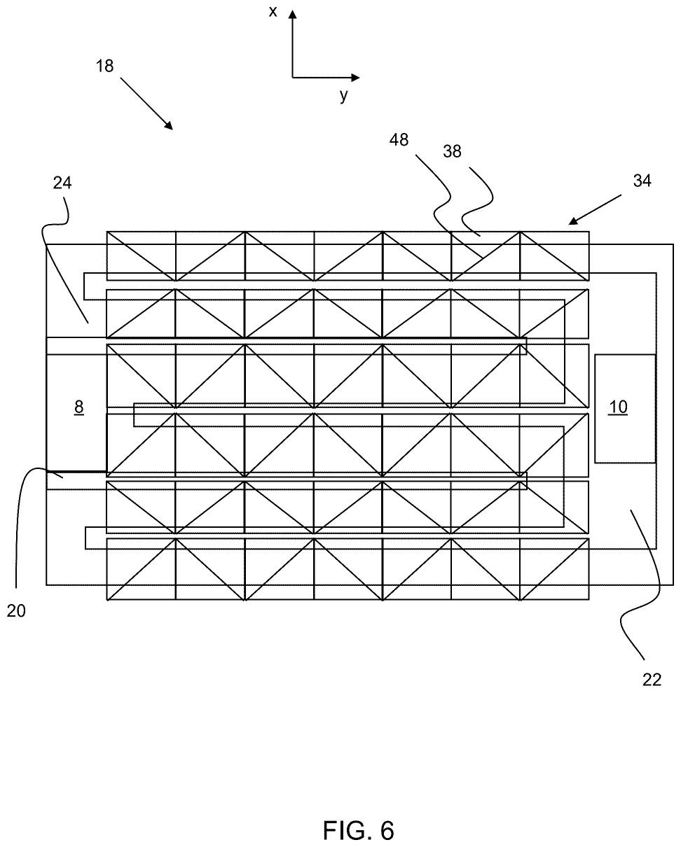

FIG. 6 shows a schematic top view of a HV semiconductor device 18 with a field plate structure 34. The device 18 has a multi-finger layout comprising six fingers (arranged S-D-S-D-S-D-S), but the field plate structure can be configured for a different device having a single finger (S-D) or a different number of fingers. The HV semiconductor device 18 may be one of the LDMOS transistors 6 described with reference to FIG. 1 above. The drift region 24 extends between the source region 20 and the drain region 22 connected to source contact 8 and drain contact 10 respectively. Rows of pairs of biased field plates 38 are arranged to cover the drift region. Underlying floating field plates are not shown. The gap 48 between the biased field plates 38 comprises a zig-zag pattern. In some embodiments, the field plate structure 34 covers substantially the whole HV semiconductor device 18, which can then allow free metal routing over the device.

With the slot in this arrangement, running diagonally in a straight line, there is a step-wise quasi-linear potential distribution (see e.g. graph in FIG. 3 described above) resulting in a substantially uniform electric field. By changing the shape of the slot the potential distribution can be made non-linear. This can allow the resulting electric field to be engineered freely. For example, the electric field can be pushed left or right.

This may be of particular advantage for covering curved parts of the drift region, such as the region around the drain 10 in FIG. 1 described above. In these race-track shaped end pieces of the drift region (also called the termination regions) it can be a challenge to have a uniform electric field, which may be solved by providing a field plate structure as described herein.

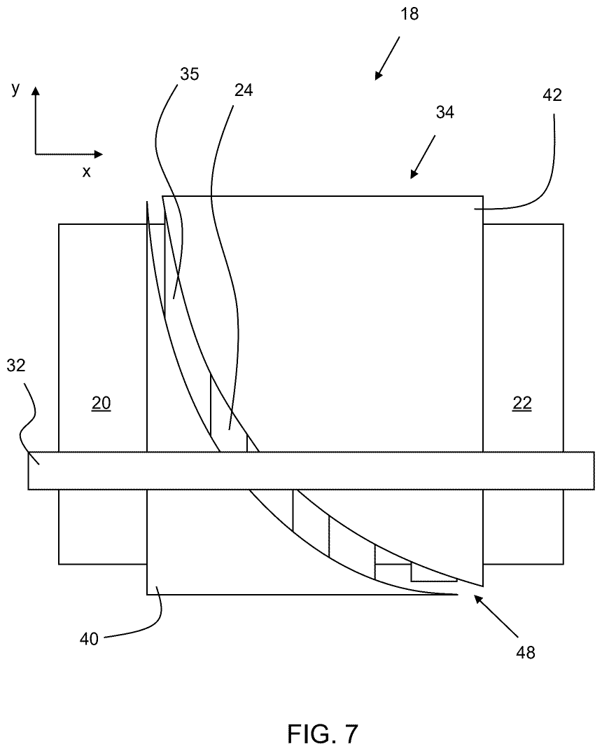

FIG. 7 shows a schematic top view of a HV semiconductor device 18 with a field plate structure 34. The field plate structure 34 comprises an array of floating field plates 35 and a pair of biased field plates 38. The pair of biased field plates 38 comprises a first field plate 40 connected to a low voltage point (e.g. the source) and a second field plate 42 connected to a high voltage point (e.g. the drain). The gap 48 between the field plates 40, 42 has a curved shape, to provide a non-linear change in potential at the floating field plates 35 in the x-direction.

An alternative solution provides a field plate structure comprising a metal layer over the drift region, which has a substantially straight slot and which does not require underlying floating field strips. The slot divides the metal layer into two parts (two field plates), whereby one part is connected to the low voltage terminal and the other part is connected to the high voltage terminal of the HV semiconductor device. In one case, the length of the field plates is not substantially longer than a height of the metal layer over the drift region. Therefore, this solution may be more effective for devices having a shorter length of the drift region (corresponding to lower voltages). This limitation depends on the given CMOS technology i.e. the number of metal layers and interlayer dielectric thickness.

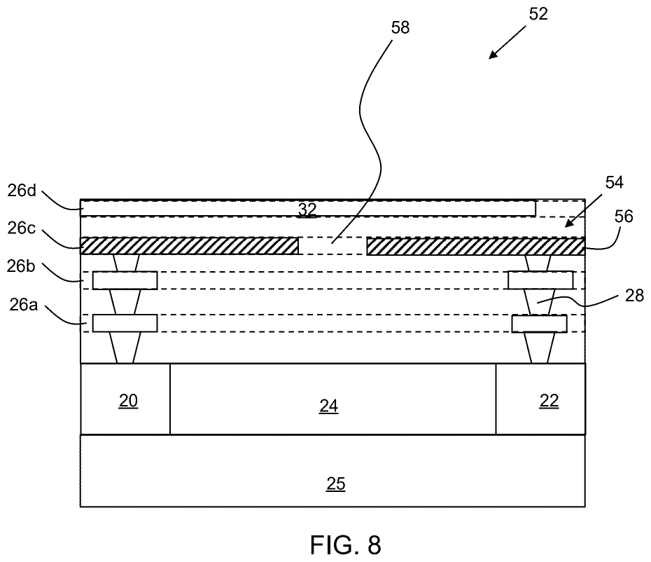

FIG. 8 shows a schematic cross section of a HV device 52 comprising a field plate structure 54 comprising a metal layer 56 with a single slot 58 substantially in the middle over the drift region 24. Apart from the slot 58, the metal layer 56 covers the whole length of the drift region 24 (and may also cover the whole width of the drift region 24). The slot 58 is substantially perpendicular to the width direction (y) of the HV device 52. The field plate structure 54 is located in the third metal layer 26c (Metal 3), but, depending on the length of the drift region, may have to be arranged in a lower or a higher metal layer (e.g. Metal 4 or Metal 5) or any other conductive layer such as poly-Si, to provide a sufficiently uniform electric field distribution. The slot 58 may have a width in the range of 1 μm to 5 μm. The field plate structure 54 is normally connected to the drain and source region by the underlying metal layers 26a to 26b and vias 28.

It is an advantage of this embodiment, and related embodiments, that there can be a complete metal covering at the top of the device. For example, the metal line 32 and/or further metal lines or routing in the fourth metal layer 26d, or higher metal levels, can completely cover the drift region 24 and/or the field plate structure 54.

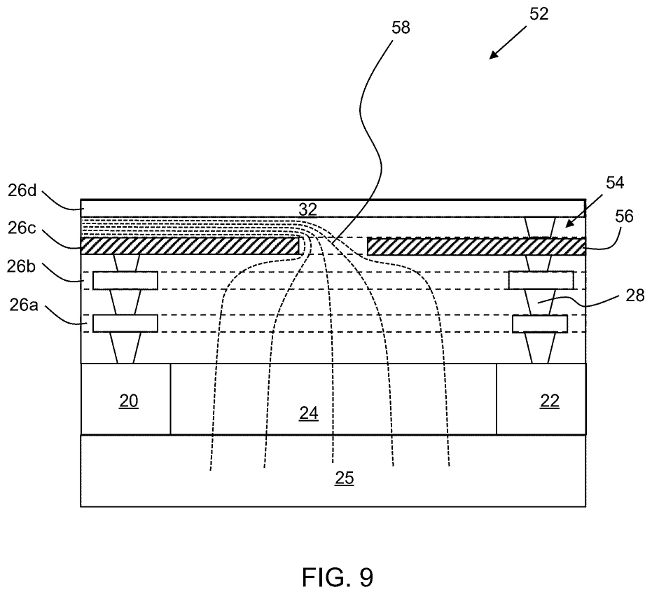

FIG. 9 shows a schematic cross section of a HV semiconductor device 18 (e.g. an LDMOS), with a field plate structure 54 comprising a metal layer 56 with a single slot 58 therein. The HV semiconductor device 18 may be the LDMOS transistor 6 described in relation to FIG. 1 above. The device 18 comprises a source region 20, a drain region 22 and a drift region 24 between. The device 18 comprises a plurality of metal layers 26a to 26d, being Metal 1 (Metal One) 26a (closest to the underlying semiconductor layer), Metal 2 (Metal Two) 26b, Metal 3 (Metal Three) 26c, and Metal 4 (Metal Four) 26d. The metal layers 26a to 26d are typically formed in a CMOS back-end-of-line (BEOL) process to form a backend stack. The metal layers 26a to 26d are separated by interdielectric layers (e.g. comprising silicon oxide) and connected by vias 28 going through the interdielectric layers. The field plate structure 54 causes the electric field lines 30 (dashed lines) to be substantially uniformly distributed in and above the drift region 24.

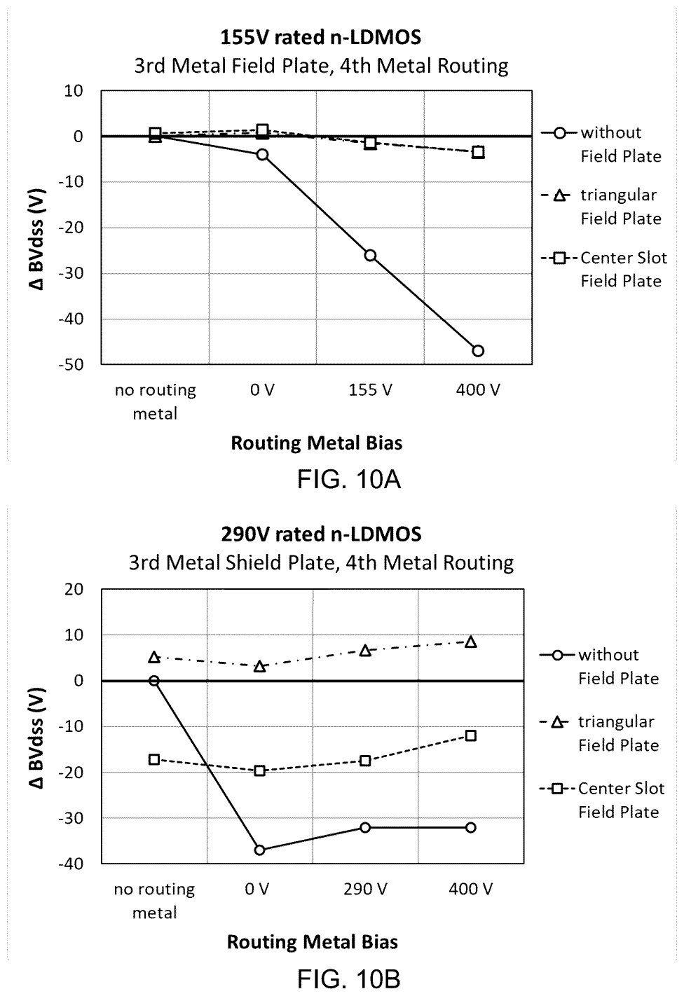

FIG. 10A and 10B show graphs plotting the change in breakdown drain to source voltage (BVdss) for the two different embodiments described above as compared to a bare NMOS device (without a field plate structure).

FIG. 10A plots A BVdss against voltage applied to a metal plate in the fourth metal layer (Metal 4) over the drift region for a 155V NMOS device. As can be seen, both the embodiment with the array of floating field plates and a pair of biased triangular field plates, and the embodiment with a central slot provide significant improvement over the bare NMOS device. The effect is particularly noticeable at high voltages (155 V and 400 V in the graph).

FIG. 10B plots A BVdss against voltage applied to a metal plate in the fourth metal layer (Metal 4) over the drift region for a 290V NMOS device. In this case, the triangular field plate embodiment provides better performance compared to the central slot embodiment, but both embodiments improve on the case without field plate.

The embodiments described allow a complete metal covering at the top of the device. This provides an improvement in the design of high-power devices. The embodiments described allow not only small connection wires for “signals” surrounded by large structures for their protection, but also allow the connection of large metal structures, polygons and/or complete layers to allow a low ohmic connection and/or low thermal resistance.

In general, embodiments described herein provide an integrated circuit (IC) comprising a high voltage region comprising a high voltage semiconductor device (e.g. an LDMOS FET) comprising a first doped region, a second doped region, and a drift region located between the first doped region and the second doped region, and a low voltage region comprising a plurality of low voltage semiconductor devices. The circuit further comprises a plurality of stacked metal layers (e.g. six metal layers) comprising metal lines configured to provide electrical connections to the high voltage semiconductor device and to the plurality of low voltage semiconductor devices. A metal structure overlaps the drift region. The circuit further comprises a field plate structure arranged between the metal structure and the drift region, wherein the field plate structure comprises an array of floating field plates in a first layer, and a pair of biased field plates in a second layer, wherein the pair of biased field plates overlaps the array of floating field plates.

The device may be a lateral PIN-Diode, wherein the first doped region is the n-type region being a cathode region of the device, and the second doped region is the p-type region being an anode region of the device. The device may be an LDMOS transistor, wherein the first doped region is a drain region, and the second doped region is a source region. Alternatively, the device may be a junction field effect transistor (JFET) or an insulated-gate bipolar transistor (IGBT) or another HV transistor, such as a lateral HV bipolar transistor. For a transistor, the first doped region may be a collector region or a drain region and the second doped region an emitter region or a source region. For a diode, the first doped region may be a cathode region and the second doped region an anode region. The first doped region may be an n-type region connected to a high voltage (HV) point/terminal, and the second doped region may be a p-type region connected to a low voltage (LV) point/terminal. When the device is a bipolar device (e.g. an IGBT), the first doped region and the second doped region can have the same type of doping. For example, the first doped region and the second doped region may both be p-type regions.

The metal structure may be a metal line or metal plate, and may be indirectly connected to the first doped region or the second doped region. For example, the metal structure may be a wide (low resistance) metal line carrying a high voltage to the first doped region (e.g. to the drain of an LDMOS). In order to reduce resistance, the metal structure may cover a major portion of the drift region. The metal structure could normally distort and concentrate the electric field lines in the drift region and thereby negatively affect the breakdown behaviour of the high voltage semiconductor device. The field plate structure between the metal line and the drift region mitigates this, and can provide an even distribution of the electric field in the drift region.

The plurality of stacked metal layer may comprise Metal 1, Metal 2, Metal 3, Metal 4, Metal 5 and Metal 6, wherein metal 1 is closest to the underlying silicon and doped semiconductor regions. The device may comprise fewer or more metal layers, depending on the particular technology used. For example, 28 nm CMOS technology can have up to twelve metal layers. Metal 6 may be the top metal layer, spaced vertically furthest apart from the silicon. Metal 1 can be directly connected to the doped semiconductor regions (e.g. to the first doped and second doped regions) and connected to Metal 2 and other metal layers in the plurality by vias.

The first doped region and the second doped region may be formed in an active silicon layer (e.g. an epitaxial silicon layer) on a substrate. The substrate may be a silicon substrate, or a SOI substrate comprising a buried oxide (BOX) layer. In other embodiments, the substrate may be silicon-on-sapphire, or GaN-on-Si.

The floating field plates may have an extended dimension arranged substantially perpendicular to the current through the drift region when in use. For example, the floating field plates may be strips arranged perpendicular to the gap between the source and drain of a transistor. The drift region may comprise a substantially rectangular area with one side being at a first interface to the first doped region and a second, opposite, side being at a second interface to the second doped region. The floating field plates may then be arranged in parallel with the first and second sides. The floating field plates may have a substantially rectangular shape. Typically, all floating field plates in in the array have the same dimensions. For example, each field plate may have a same width and may have a same length. The array may extend from over the second doped region to over the first doped region so as to substantially cover a whole length of the drift region. The array may also be present only over the drift regions in case the source and drain extend somewhat into the drift regions forming short source and drain field plates. The extended dimension (along y) of the floating field plates is at least sufficient to cover the metal structure over the drift region. Typically the extended dimension is in the range of 1 μm to 10 mm, depending on the width of the drift region. The rectangular shape has a short dimension (along x) in the range of 1 μm to 5 μm. A gap between neighboring floating field plates may be in the range of 1 μm to 5 μm.

The pair of biased field plates may comprise a first field plate electrically connected to a low voltage point, and a second field plate electrically connected to a high voltage point. The pair of biased field plates may comprise a first field plate electrically connected to the first doped region, and a second field plate electrically connected to the second doped region. The first field plate and the second field plate are separated by a gap (such as a rectangular slot) in the second layer, and the gap can be arranged diagonally over the drift region. Diagonal in this sense means that the gap is at an angle to the width dimension of the drift region. The drift region may comprise a rectangular area, and the gap may extend piecewise diagonally over this rectangular area in a meandering or zig-zag like manner. For example, in one embodiment, the gap extends from over one corner of the drift region to a diagonally opposite corner of the drift region. The angle of the gap relative to a width direction of the drift region may be in the range of 30 degrees to 60 degrees. The gap may have a width in the range of 1 μm to 5 μm.

The pair of biased field plates may cover a substantially rectangular area, for example, wherein each of the first and second field plates has a substantially triangular shape (also referred to as a wedge shape). For example, each field plate of the pair may have the shape of a right angled triangle. The hypotenuses may face each other forming a gap between them. Due to manufacturing constraints, the triangular shape may have flat or rounded tips. The edges of the triangular shape along diagonal lines (e.g. the edge of the hypotenuse) may be jagged. For example, the patterning may be constrained to linear movements along x and y, causing a stepped diagonal line. The rectangular area may completely cover (apart from where the gap is located) the underlying array of floating field plates. The pair of biased field plates can be arranged with respect to the array of floating field plates such that an electric potential increases substantially linearly from a first floating field plate located closest to the second doped region to a last floating field plate located closest to the first doped region.

The first layer (comprising the array of floating field plates) may be Poly-Si, or Metal 1 or Metal 2 of the plurality of stacked metal layers. For example, the array of floating field plates can be formed in the poly layer (e.g. the same poly layer that is used to form the gate poly of a transistor), the metal layer closest to the underlying silicon or the metal layer second closest to the underlying silicon for example.

The second layer (comprising the pair of biased field plates) may be Metal 1, Metal 2 or Metal 3 of the plurality of stacked metal layers (depending on the layer in which the floating field plates are located). In one case, the pair of biased field plates is located in the metal layer directly above the layer with the floating field plates. That is, there may be no further metal layer between the first layer and second layer.

Further embodiments described herein can provide an integrated circuit (IC) comprising a high voltage region comprising a high voltage semiconductor device (e.g. an LDMOS FET) comprising a first doped region, a second doped region, and a drift region located between the first doped region and the second doped region, and a low voltage region comprising a plurality of low voltage semiconductor devices. The circuit further comprises a plurality of stacked metal layers (e.g. six metal layers) comprising metal lines configured to provide electrical connections to the high voltage semiconductor device and to the plurality of low voltage semiconductor devices. A metal structure is connected to the high voltage semiconductor device and overlaps the drift region. The circuit further comprises a field plate structure arranged between the metal structure and the drift region, wherein the field plate structure comprises a continuous metal layer with a slot located under the metal structure. The second doped region may be connected to the low voltage region.

The slot separates the metal layer into two parts (two field plates). A first part may be connected to the first doped region and a second part may be connected to the second doped region. The two parts of the metal layer are continuous over the drift region, but other parts of the metal layer may be used and comprise other metal connections laterally distanced from the drift region. The slot is typically a single slot, and may be located substantially in the centre of the drift region (e.g. equidistant from the source and drain). In other embodiments, the slot may be within 40% to 60% of the centre. The slot may have a width in the range of 1 μm to 5 μm, and in one case between 2 μm and 4 μm.

The field plate structure may be located in Metal 4 or Metal 5 of the plurality of stacked metal layers. For example, the plurality of stacked metal layers may include 6 metal layers and the field plate structure may be located in the second metal layer from the top, while the metal structure may be located in Metal 6 (the top metal layer). The required height of the field plate structure depends on the length of the drift region. For a short drift region, a lower metal layer (e.g. Metal 2 or Metal 3) may be used, which allows for greater freedom of metal routing, as there are more available metal layers over the field plate structure. For a device with a long drift region, a higher metal layer may need to be used. The height of the field plate structure may be greater or equal to half the length of the drift region.

While specific embodiments of the invention have been described above, it will be appreciated that the invention may be practiced otherwise than as described. The descriptions above are intended to be illustrative, not limiting. It will be apparent to one skilled in the art that modifications may be made to the invention as described without departing from the scope of the claims set out below.

Each feature disclosed or illustrated in the present specification may be incorporated in the invention, whether alone or in any appropriate combination with any other feature disclosed or illustrated herein.

What is claimed is:

1. An integrated circuit comprising:
a high voltage semiconductor device comprising a first doped region, a second doped region, and a drift region located between the first doped region and the second doped region;
a plurality of stacked metal layers;
a metal structure overlapping the drift region;
a field plate structure arranged between the metal structure and the drift region, wherein the field plate structure comprises:
an array of floating field plates; and
a pair of field plates, comprising first and second field plates, wherein the pair of field plates overlaps the array of floating field plates; and
wherein the first field plate and the second field plate are separated by a gap, and wherein the gap is arranged diagonally over the drift region.

2. An integrated circuit according to claim 1, wherein said array of floating field plates are formed in a polysilicon layer or a first metal layer of said plurality of stacked metal layers.

3. An integrated circuit according to claim 1, wherein said pair of field plates are formed in a second metal layer of said plurality of stacked metal layers.

4. An integrated circuit according to claim 1, wherein the floating field plates have an extended dimension arranged substantially perpendicular to a current through the drift region when in use.

5. An integrated circuit according to claim 1, wherein the floating field plates have a rectangular shape.

6. An integrated circuit according to claim 5, wherein the rectangular shape has a short side with a dimension in the range of 1 μm to 5 μm, and a long side with a dimension in the range of 1 μm to 10 mm.

7. An integrated circuit according to claim 1, wherein the pair of field plates comprises a first field plate electrically connected to a low voltage point, and a second field plate electrically connected to a high voltage point.

8. An integrated circuit according to claim 1, wherein the first field plate is electrically connected to the first doped region, and the second field plate is electrically connected to the second doped region.

9. An integrated circuit according to claim 1, wherein the first field plate and the second field plate are formed from one of said plurality of stacked metal layers.

10. An integrated circuit according to claim 9, wherein the gap has a width in the range of 0.5 μm to 5 μm.

11. An integrated circuit according to claim 1, wherein the pair of field plates covers a substantially rectangular area, and wherein each of the first and second field plates has a triangular shape.

12. An integrated circuit according to claim 1, wherein the pair of field plates are arranged with respect to the array of floating field plates such that an electric potential increases substantially linearly from a first floating field plate located closest to the second doped region to a last floating field plate located closest to the first doped region.

13. An integrated circuit according to claim 1, further comprising a one or more further pairs of field plates arranged over the drift region and overlapping the array of floating field plates.

14. An integrated circuit according to claim 13, wherein the gap between field plates of the pair of field plates and a gap between field plates of the one or more further pairs of field plates together form a zig-zag pattern over the drift region.

15. An integrated circuit as claimed in claim 1, wherein said pair of field plates are biased field plates.

16. An integrated circuit comprising:
a high voltage semiconductor device comprising a first doped region, a second doped region, and a drift region located between the first doped region and the second doped region;
a plurality of stacked metal layers;
a metal structure overlapping the drift region; and
a field plate structure arranged between the metal structure and the drift region, wherein the field plate structure comprises a metal layer which is connected to said first and second doped regions and which defines a slot;
wherein the slot is located under the metal structure; and
wherein said slot is the only slot, formed in said metal layer, which is located under the metal structure.

17. An integrated circuit as claimed in claim 16, wherein said slot separates the metal layer into two parts and wherein each part provides a continuous metal cover over the drift region.

18. An integrated circuit as claimed in claim 16, wherein said metal layer is formed in one of said plurality of stacked metal layers.

19. An integrated circuit according to claim 16, wherein said metal layer is located in Metal 4 or Metal 5 of said plurality of stacked metal layers.

20. An integrated circuit according to claim 16, wherein the slot has a width dimension in the range of 1 μm to 5 μm.

21. An integrated circuit as claimed in claim 16, wherein the slot has a longitudinal axis substantially perpendicular to a direction from said first doped region to said second doped region.

22. An integrated circuit as claimed in claim 16, wherein the slot is positioned substantially half way between said first doped region and said second doped region.

23. An integrated circuit as claimed in claim 16, wherein said metal structure completely covers said drift region.

24. An integrated circuit as claimed in claim 16, wherein said metal structure completely covers said field plate structure.

25. An integrated circuit device comprising:
an integrated circuit as claimed in claim 16;
a high voltage region comprising the high voltage semiconductor device of said integrated circuit; and
a low voltage region comprising a plurality of low voltage semiconductor devices;
wherein said plurality of stacked metal layers comprises metal lines configured to provide electrical connections to the high voltage semiconductor device and to the plurality of low voltage semiconductor devices.
